(19) United States
(12) Patent Application Publication
(10) Pub. No.: US 2024/0339305 A1
(43) Pub. Date: Oct. 10, 2024

(54) SUBSTRATE SUPPORT AND PLASMA PROCESSING APPARATUS

(71) Applicant: Tokyo Electron Limited, Tokyo (JP)

(72) Inventor: Hajime TAMURA, Miyagi (JP)

(73) Assignee: Tokyo Electron Limited, Tokyo (JP)

(21) Appl. No.: 18/748,263

(22) Filed: Jun. 20, 2024

Related U.S. Application Data
(63) Continuation of application No. PCT/JP2022/046432, filed on Dec. 16, 2022.

(30) Foreign Application Priority Data
Dec. 23, 2021 (JP) 2021-209632

(51) Int. Cl. H01J 37/32

(52) U.S. Cl. CPC H01J 37/32724; H01J 37/32642; H01J 2237/002; H01J 2237/2007

(57) ABSTRACT

A substrate support and a plasma processing apparatus for placing an edge ring on an electrostatic chuck with high positional accuracy. A substrate support includes: a base, a first electrostatic chuck region disposed at an upper portion of the base and having a substrate support surface, and the first electrostatic chuck holding a substrate on the substrate support surface; and a second electrostatic chuck region disposed at the upper portion of the base to surround the first electrostatic chuck region and having a ring support surface, and the second electrostatic chuck holding an edge ring on the ring support surface. The second electrostatic chuck region is provided with a positioning pin of the edge ring, the positioning pin being formed of a material having a linear expansion coefficient substantially equal to a linear expansion coefficient of a material forming the second electrostatic chuck region.

### CROSS-REFERENCE TO RELATED APPLICATIONS

This application is a bypass continuation application of International Application No. PCT/JP2022/046432 having an international filing date of Dec. 16, 2022, and designating the United States, the international application being based upon and claiming the benefit of priority from Japanese Patent Application No. 2021-209632, filed on Dec. 23, 2021, the entire contents of each are incorporated herein by reference.

### TECHNICAL FIELD

The present disclosure relates to a substrate support and a plasma processing apparatus.

### BACKGROUND

Patent Literature 1 discloses a plasma processing system in which an edge ring is transferred into a plasma processing apparatus by a transfer device and the edge ring is placed on an electrostatic chuck of a stage.

### CITATION LIST

### Patent Documents

Patent Document 1: JP2021-61415A

### SUMMARY

In one aspect, the present disclosure provides a substrate support and a plasma processing apparatus for placing an edge ring on an electrostatic chuck with high positional accuracy.

To solve the above-described problem, according to one aspect, a substrate support is provided, which includes: a base; a first electrostatic chuck region disposed at an upper portion of the base, the first electrostatic chuck region having a substrate support surface, and being configured to hold a substrate on the substrate support surface; and a second electrostatic chuck region disposed at the upper portion of the base to surround the first electrostatic chuck region, the second electrostatic chuck region having a ring support surface, and being configured to hold an edge ring on the ring support surface, in which the second electrostatic chuck region is provided with a positioning pin of the edge ring, the positioning pin being formed of a material having a linear expansion coefficient substantially equal to a linear expansion coefficient of a material forming the second electrostatic chuck region.

According to one aspect, a substrate support and a plasma processing apparatus for placing an edge ring on an electrostatic chuck with high positional accuracy are provided.

### BRIEF DESCRIPTION OF DRAWINGS

FIG. 1 shows an example of a configuration of a plasma processing apparatus.

FIG. 2 is an example of a partially enlarged cross-sectional view of a substrate support according to a first embodiment.

FIG. 3 is an example of a plan view of a main body.

FIG. 4 is an example of a bottom view of a ring assembly.

FIG. 5A is an example of a side view of a positioning pin.

FIG. 5B is an example of a top view of the positioning pin.

FIG. 5C is an example of a cross-sectional view of the positioning pin.

FIG. 6 is an example of a configuration diagram of another positioning pin.

FIG. 7 is an example of a partially enlarged cross-sectional view of a substrate support according to a second embodiment.

### DETAILED DESCRIPTION

Hereinafter, various exemplary embodiments will be described in detail with reference to the drawings. Further, like reference numerals will be given to like or corresponding parts throughout the drawings.

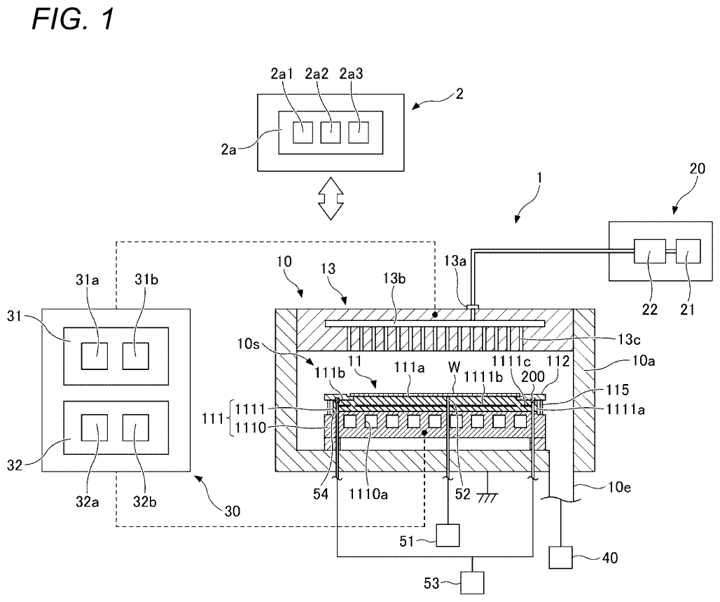

An example of a configuration of a plasma processing system will be described with reference to FIG. 1. FIG. 1 is a view for explaining an example of a configuration of a capacitively-coupled plasma processing apparatus.

The plasma processing system includes a capacitively-coupled plasma processing apparatus 1 and a controller 2. The capacitively-coupled plasma processing apparatus 1 includes the plasma processing chamber 10, a gas supply 20, a power source 30, and an exhaust system 40. Further, the plasma processing apparatus 1 includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 has at least one gas supply port for supplying at least one processing gas into the plasma processing space 10s, and at least one gas exhaust port for exhausting the gas from the plasma processing space. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

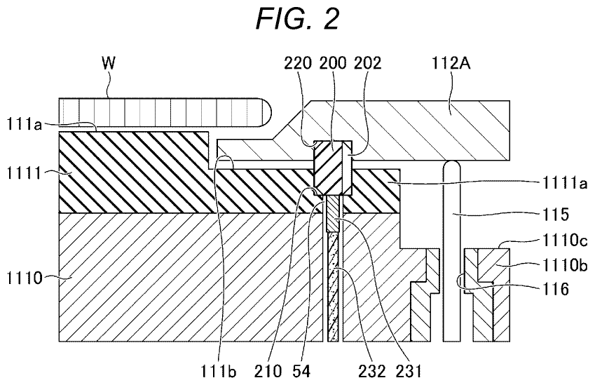

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a, an electrostatic electrode 1111b disposed in the ceramic member 1111a, and an annular electrostatic electrode 1111c disposed in the ceramic member 1111a. The ceramic member 1111a has the central region 111a. In one embodiment, the ceramic member 1111a also has the annular region 111b. The electrostatic electrode 1111b is provided in the central region 111a to support the substrate W. The annular electrostatic electrode 1111c is provided in the annular region 111b to support the ring assembly 112. That is, the ceramic member 1111a and the electrostatic electrode 1111b in the central region 111a constitute a first electrostatic chuck region that attracts and holds the substrate W. Further, the ceramic member 1111a and the annular electrostatic electrode 1111c in the annular region 111b constitute a second electrostatic chuck region that attracts and holds an edge ring 112A (see FIG. 2 to be described later) of the ring assembly 112. The ceramic member 1111a in the central region 111a is an example of a material forming the first electrostatic chuck region. The ceramic member 1111a in the annular region 111b is an example of a material forming the second electrostatic chuck region. The electrostatic chuck 1111 is described as an annular electrostatic chuck in which the annular electrostatic electrode 1111c is disposed in the ceramic member 1111a in the annular region 111b to attract the edge ring 112A (see FIG. 2 to be described later) of the ring assembly 112, but is not limited thereto. Another member that surrounds the electrostatic chuck 1111, such as an annular electrostatic chuck or an annular insulating member, may have the annular region 111b. In this case, the edge ring 112A (see FIG. 2 to be described later) of the ring assembly 112 may be disposed on the annular electrostatic chuck or the annular insulating member, or may be disposed on both the electrostatic chuck 1111 and the annular insulating member. Further, at least one RF/DC electrode coupled to a radio frequency (RF) power source 31 and/or a direct current (DC) power source 32 to be described below may be disposed inside the ceramic member 1111a. In this case, at least one RF/DC electrode functions as the lower electrode. In a case where the bias RF signal and/or the DC signal to be described later are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Accordingly, the substrate support 11 includes at least one lower electrode.

The ring assembly 112 includes one or more annular members. In one embodiment, the one or more annular members include one or more edge rings including the edge ring 112A (see FIG. 2 to be described later) and at least one cover ring. The edge ring (e.g., 112A) is formed of a conductive material or an insulating material, and the cover ring is formed of an insulating material.

Further, the substrate support 11 may include a temperature control module configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed inside the base 1110, and one or more heaters are disposed in the ceramic member 1111a of the electrostatic chuck 1111. Further, the substrate support 11 may include a heat transfer gas supply 51 configured to supply a heat transfer gas to a gap between a rear surface of the substrate W and the central region 111a. The heat transfer gas supply 51 supplies the heat transfer gas to the gap between the rear surface of the substrate W and the central region 111a through a gas flow path penetrating the base 1110 and a supply hole 52 penetrating the electrostatic chuck 1111. Further, the substrate support 11 may include a heat transfer gas supply 53 configured to supply a heat transfer gas to a gap between a rear surface of the edge ring 112A (see FIG. 2 to be described later) of the ring assembly 112 and the annular region 111b. The heat transfer gas supply 53 supplies the heat transfer gas to the gap between the rear surface of the edge ring 112A (see FIG. 2 to be described later) of the ring assembly 112 and the annular region 111b through a gas flow path penetrating the base 1110 and a supply hole 54 penetrating the electrostatic chuck 1111.

Further, the substrate support 11 may include, for example, three lift pins that can be raised and lowered from the substrate support surface in the central region 111a. By raising the lift pins from the substrate support surface, the substrate W placed on the substrate support surface can be lifted by the lift pins. That is, the lift pins 115 lift the edge rings (e.g., edge ring 112A), and the edge rings (e.g., edge ring 112A) have a reduced thickness portion that contacts (e.g., directly contacts) an underside (e.g., bottom surface) of the substrate W to lift the substrate W. The reduced thickness portion is directly connected (e.g., directly adjacent to) an inclined portion that has a gradually increasing thickness from the reduced thickness portion to a maximum thickness of the edge ring. As a result, a transfer device can receive the substrate W lifted by the lift pins. Further, the transfer device can transfer the substrate W to the lift pins. As a result, the lift pins are lowered on the substrate support surface, and thus the substrate W supported by the lift pins can be transferred to the substrate support surface.

Further, the substrate support 11 may include, for example, three lift pins 115 that can be raised and lowered at a base outer peripheral portion 1110b (see FIG. 2 to be described later) of the base 1110. In this case, a lift pin insertion portion 116 (see FIG. 2 to be described later) for inserting each lift pin 115 is formed in the base outer peripheral portion 1110b. By raising the lift pins 115 from a base outer peripheral portion upper surface 1110c of the base outer peripheral portion 1110b (see FIG. 2 to be described later), the edge ring 112A (see FIG. 2 to be described later) of the ring assembly 112 placed on the ring support surface can be lifted by the lift pins 115. As a result, the transfer device can receive the edge ring 112A of the ring assembly 112 lifted by the lift pins 115. Further, the transfer device can transfer the edge ring 112A of the ring assembly 112 to the lift pins 115. As a result, by lowering the lift pins 115 at the base outer peripheral portion 1110b, the edge ring 112A of the ring assembly 112 supported by the lift pins 115 can be transferred to the ring support surface.

Further, the annular region 111b of the electrostatic chuck 1111 is provided with a positioning pin 200 for positioning the edge ring 112A (see FIG. 2 to be described later) of the ring assembly 112.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include one or more flow rate modulation devices that modulate or pulse flow rates of at least one processing gas.

The power source 30 includes an RF power source 31 coupled to the plasma processing chamber 10 via at least one impedance matching circuit. The RF power source 31 is configured to supply at least one RF signal (RF power) to at least one lower electrode and/or at least one upper electrode. As a result, plasma is formed from at least one processing gas supplied into the plasma processing space 10s. Accordingly, the RF power source 31 may function as at least a portion of a plasma generator configured to generate plasma from one or more processing gases in the plasma processing chamber 10. Further, supplying the bias RF signal to at least one lower electrode can generate a bias potential in the substrate W to attract an ionic component in the formed plasma to the substrate W.

In one embodiment, the RF power source 31 includes a first RF generator 31a and a second RF generator 31b. The first RF generator 31a is configured to be coupled to at least one lower electrode and/or at least one upper electrode via at least one impedance matching circuit to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate the bias RF signal (bias RF power). A frequency of the bias RF signal may be the same as or different from a frequency of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one lower electrode. Further, in various embodiments, at least one of the source RF signal and the bias RF signal may be pulsed.

Further, the power source 30 may include a DC power source 32 coupled to the plasma processing chamber 10. The DC power source 32 includes a first DC generator 32a and a second DC generator 32b. In one embodiment, the first DC generator 32a is configured to be connected to at least one lower electrode to generate the first DC signal. The generated first bi as DC signal is applied to at least one lower electrode. In one embodiment, the second DC generator 32b is configured to be connected to at least one upper electrode to generate a second DC signal. The generated second DC signal is applied to at least one upper electrode.

In various embodiments, at least one of the first and second DC signals may be pulsed. In this case, the sequence of voltage pulses is applied to at least one lower electrode and/or at least one upper electrode. The voltage pulse may have a pulse waveform of a rectangle, a trapezoid, a triangle or a combination thereof. In one embodiment, a waveform generator for generating a sequence of voltage pulses from the DC signal is connected between the first DC generator 32a and at least one lower electrode. Accordingly, the first DC generator 32a and the waveform generator configure a voltage pulse generator. In a case where the second DC generator 32b and the waveform generator configure the voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be also provided in addition to the RF power source 31, and the first DC generator 32a may be also provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

The controller 2 processes computer-executable instructions for instructing the plasma processing apparatus 1 to execute various steps described herein below. The controller 2 may be configured to control the respective components of the plasma processing apparatus 1 to execute the various steps described herein below. In an embodiment, part or all of the controller 2 may be included in the plasma processing apparatus 1. The controller 2 may include a processor 2a1, a storage unit 2a2, and a communication interface 2a3. The controller 2 is implemented by, for example, a computer 2a. The processor 2al may be configured to read a program from the storage unit 2a2 and perform various control operations by executing the read program. The program may be stored in advance in the storage unit 2a2, or may be acquired via a medium when necessary. The acquired program is stored in the storage unit 2a2, and is read from the storage unit 2a2 and executed by the processor 2al. The medium may be various storing media readable by the computer 2a, or may be a communication line connected to the communication interface 2a3. The processor 2al may be a Central Processing Unit (CPU) and can be designated as “circuitry”. The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

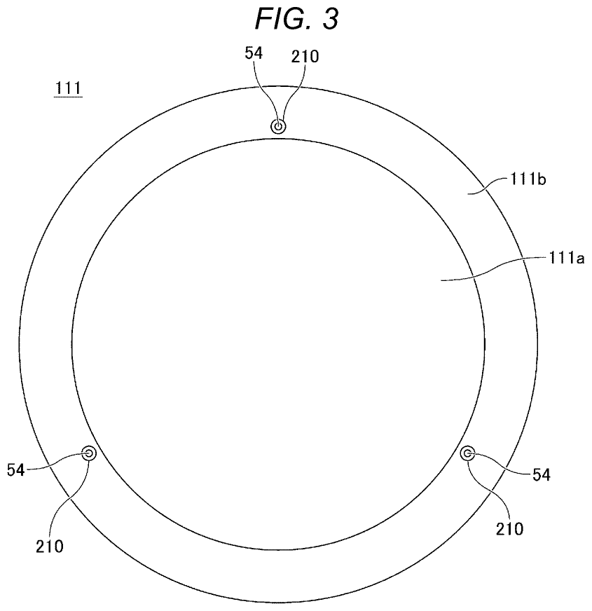

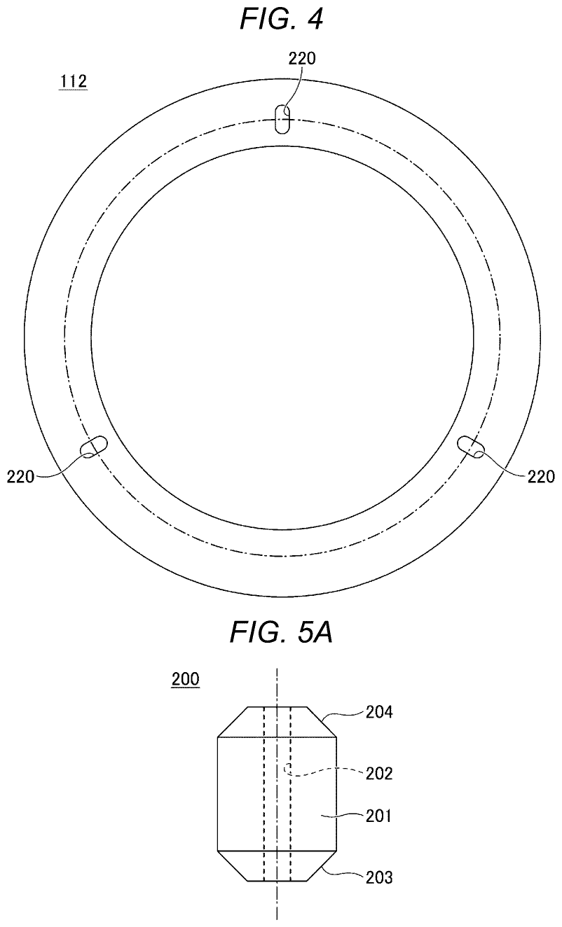

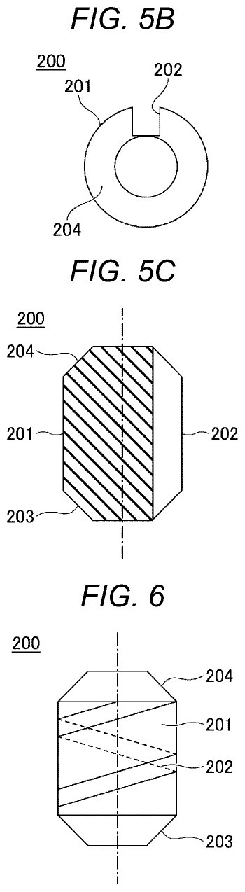

Next, a mechanism for positioning the edge ring 112A when the edge ring 112A of the ring assembly 112 is placed in the annular region 111b will be described with reference to FIGS. 2 to 6. FIG. 2 is an example of a partially enlarged cross-sectional view of the substrate support 11 according to a first embodiment. FIG. 3 is an example of a plan view of the main body 111. FIG. 4 is an example of a bottom view of the edge ring 112A. FIGS. 5A to 5C are examples of configuration diagrams of the positioning pin 200. FIG. 5A shows an example of a side view of the positioning pin 200. FIG. 5B shows an example of a top view. FIG. 5C shows an example of a cross-sectional view. FIG. 6 is an example of a configuration diagram of another positioning pin 200.

A pin insertion portion 210 for inserting the positioning pin 200 is formed in the annular region 111b of the electrostatic chuck 1111. The pin insertion portion 210 is formed as a recess having a bottom surface in the ring support surface. Here, as shown in FIG. 2, the pin insertion portion 210 communicates with the supply hole 54. That is, the pin insertion portion 210 is formed as a counterbore having an enlarged diameter on a ring support surface side of the supply hole 54. In other words, the supply hole 54 is connected to a bottom surface of the pin insertion portion 210. Here, as shown in FIG. 3, a plurality of pin insertion portions 210 are provided in a circumferential direction. In the example shown in FIG. 3, three pin insertion portions 210 are provided at equal intervals in the circumferential direction.

Further, by sharing the pin insertion portion 210 and the supply hole 54, it is not necessary to form any new hole in the annular electrostatic electrode 1111c that attracts the edge ring 112A. Accordingly, an attraction area of the annular electrostatic electrode 1111c can be maintained. As a result, it is possible to improve alignment accuracy of the edge ring 112A without reducing an attraction force on the edge ring 112A by the annular electrostatic electrode 1111c.

The edge ring 112A includes a pin engagement portion 220 that engages with the positioning pin 200. The pin engagement portion 220 is formed as a recess (e.g., groove or cut-out) having a ceiling surface on a bottom surface side of the edge ring 112A. As shown herein in FIG. 4, a plurality of pin engagement portions 220 are provided to correspond to the positioning pins 200 inserted into the pin insertion portions 210 in the circumferential direction. In the example shown in FIG. 4, three pin engagement portions 220 are provided at equal intervals in the circumferential direction.

Further, the pin engagement portion 220 may be formed in a long hole shape (e.g., slot hole shape) having a radial direction as a longitudinal direction. In this case, even when a large temperature difference occurs in the plasma processing space 10s, it is possible to prevent the main body 111 or the edge ring 112A from being damaged due to thermal expansion or contraction caused by a difference between linear expansion coefficients of the main body 111 and the edge ring 112A.

The positioning pin 200 inserted into the pin insertion portion 210 may be fixed to the annular region 111b of the ceramic member 1111a by adhesion or the like. In this case, when the lift pins 115 are raised and the edge ring 112A is lifted, the positioning pin 200 can be prevented from falling from the electrostatic chuck 1111, a member protruding toward the bottom surface of the edge ring 112A can be omitted, and thus transfer efficiency of the edge ring 112A is improved.

As shown in FIGS. 5A-5C, the positioning pin 200 is a substantially cylindrical member. The positioning pin 200 has a circumferential surface 201. A vertical gas flow path groove 202 connecting a lower end and an upper end of the positioning pin 200 is formed in the circumferential surface 201. A plurality of gas flow path grooves 202 may be formed in the circumferential surface 201. The positioning pin 200 is formed with tapers 203 and 204. As a result, a lower side of the positioning pin 200 can be easily inserted into the pin insertion portion 210. Further, when an upper side of the positioning pin 200 and the pin engagement portion 220 of the edge ring 112A are engaged, the positioning pin 200 can be easily inserted into the pin engagement portion 220. As a result, the heat transfer gas supplied from the supply hole 54 flows through the gas flow path groove 202 and is supplied to the gap between the rear surface of the edge ring 112A and the annular region 111b.

Further, the positioning pin 200 is formed of the same material as the ceramic member 1111a of the electrostatic chuck 1111 where the pin insertion portion 210 is formed (a material having the same linear expansion coefficient) or a material having substantially the same linear expansion coefficient. Further, the material of the positioning pin 200 is an insulator.

Here, the material having substantially the same linear expansion coefficient may be a material with which the positioning pin 200 or the ceramic member 1111a is not damaged due to thermal expansion or contraction when a temperature of the substrate support 11 is changed from a normal temperature to a temperature performing a processing to the substrate W. For example, the linear expansion coefficient of the material of the positioning pin 200 may be larger than the linear expansion coefficient of the material of the ceramic member 1111a, or the linear expansion coefficient of the material of the positioning pin 200 may be smaller than the linear expansion coefficient of the material of the ceramic member 1111a. In this case, since the difference between the linear expansion coefficients of the positioning pin 200 and the ceramic member 1111a is small, even when a large temperature difference occurs in the plasma processing space 10s, it is possible to prevent the positioning pin 200 and the ceramic member 1111a from being damaged due to thermal expansion or contraction caused by the difference in the linear expansion coefficients.

Further, since the difference in the linear expansion coefficients is small, it is possible to prevent a gap between the positioning pin 200 and the pin insertion portion 210 from being enlarged due to thermal expansion, and thus alignment accuracy of the edge ring 112A can be ensured.

Specifically, the positioning pin 200 is provided with a material having such a linear expansion coefficient that the ceramic member 1111a is not damaged when an amount of change in a temperature of the substrate W within a predetermined time is controlled to 200° C. or lower (for example, the temperature of the substrate W is controlled within a range of −100° C. to 100° C. within the predetermined time or the temperature of the substrate W is controlled within a range of 0° C. to 200° C. within the predetermined time, and the predetermined time is, for example, 1 second).

As the material of the ceramic member 1111a, for example, alumina (AlO₃) or yttria (Y₂O₃) can be used. Further, as the material of the positioning pin 200, for example, alumina (AlO₃), molybdenum (Mo), or titanium (Ti) can be used.

In this way, by using materials having the same or substantially the same linear expansion coefficient for the positioning pin 200 and the ceramic member 1111a, it is possible to prevent the ceramic member 1111a from being damaged due to a difference in thermal expansion or contraction. In other words, the ceramic member 1111a can be prevented from being damaged while a clearance between the pin engagement portion 220 and the positioning pin 200 is reduced. As a result, it is possible to improve the alignment accuracy of the edge ring 112A.

Further, when a voltage is applied from the power source 30 to the base 1110, the heat transfer gas ionized due to an electric potential gradient occurring in the supply hole 54 is accelerated. Here, when an electron acceleration distance in an electric potential gradient direction in the supply hole 54 extends based on a mean free path of electrons, a discharge may occur in the supply hole 54. Therefore, it is preferable to provide discharge prevention members (e.g., embedded members) 231 and 232 in the supply hole 54 to increase electron collision frequency and prevent the occurrence of the discharge. The discharge prevention member 231 (e.g., first discharge prevention member) is a member disposed closer to the edge ring 112A than the discharge prevention member 232 (e.g., second discharge prevention member), and is formed of a material having plasma resistance (for example, a conductor such as SiC). Further, the discharge prevention member 232 is formed of an insulator such as polytetrafluoroethylene (PTFE). As a result, it is possible to reduce the electron acceleration distance and prevent the discharge in the supply hole 54.

Further, as shown in FIG. 6, the positioning pin 200 is preferably formed with a spiral gas flow path groove 202 in the circumferential surface 201. As a result, it is possible to reduce the electron acceleration distance in the electric potential gradient direction and prevent the discharge in the gas flow path groove 202.

Further, the positioning pin 200 may be formed of a porous material. As a result, it is possible to prevent the discharge in the supply hole 54 and the pin insertion portion 210 while allowing the heat transfer gas to flow into the gas flow path groove 202 and the porous material provided in the positioning pin 200.

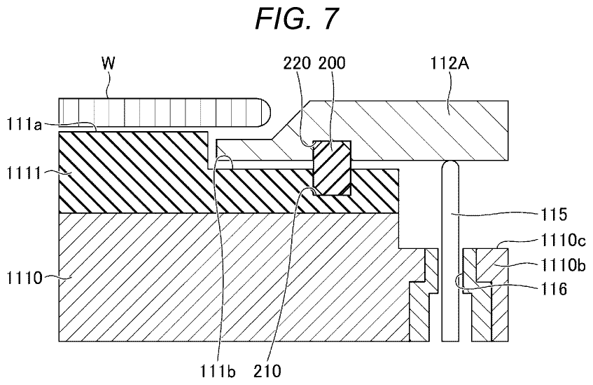

In FIG. 2, a position where the pin insertion portion 210 is formed has been described as being a position common to the supply hole 54, but the position is not limited thereto. FIG. 7 is an example of a partially enlarged cross-sectional view of the substrate support 11 according to a second embodiment.

As shown in FIG. 7, the pin insertion portion 210 may be formed at a position different from the supply hole 54. In this case, the gas flow path groove 202 formed in the circumferential surface 201 of the positioning pin 200 may be omitted. Other configurations are the same as those of the substrate support 11 shown in FIG. 2, and repeated description will be omitted.

In this configuration, the material of the positioning pin 200 is still the same material as, or a material having substantially the same linear expansion coefficient as the ceramic member 1111a of the electrostatic chuck 1111 where the pin insertion portion 210 is formed. As a result, even when a large temperature difference occurs in the plasma processing space 10s, it is possible to ensure the alignment accuracy of the edge ring 112A while preventing the positioning pin 200 and the ceramic member 1111a from being damaged due to thermal expansion or contraction caused by a difference in linear expansion coefficients.

The embodiments disclosed above include, for example, the following aspects.

### (Appendix 1)

A substrate support including:
a base;
a first electrostatic chuck region disposed at an upper portion of the base, the first electrostatic chuck region having a substrate support surface, and being configured to hold a substrate on the substrate support surface; and
a second electrostatic chuck region disposed at the upper portion of the base to surround the first electrostatic chuck region, the second electrostatic chuck region having a ring support surface, and being configured to hold an edge ring on the ring support surface, in which
the second electrostatic chuck region is provided with a positioning pin of the edge ring, the positioning pin being formed of a material having a linear expansion coefficient substantially equal to a linear expansion coefficient of a material forming the second electrostatic chuck region.

### (Appendix 2)

The substrate support according to Appendix 1, in which
the positioning pin is provided on an upper surface of the second electrostatic chuck region.

### (Appendix 3)

The substrate support according to Appendix 1 or 2, in which
the positioning pin is formed of an insulator.

### (Appendix 4)

The substrate support according to any one of Appendices 1 to 3, in which
the positioning pin is formed of a material same as the material forming the second electrostatic chuck region.

### (Appendix 5)

The substrate support according to any one of Appendices 1 to 4, in which
the positioning pin is fixed to the second electrostatic chuck region.

### (Appendix 6)

The substrate support according to any one of Appendices 1 to 5, in which
the second electrostatic chuck region has a supply hole, through which a heat transfer gas is supplied between the upper surface of the second electrostatic chuck region and the edge ring, and
a part of the positioning pin is provided inside the supply hole.

### (Appendix 7)

A substrate support including:
a base;
a first electrostatic chuck region disposed at an upper portion of the base, the first electrostatic chuck region having a substrate support surface, and being configured to hold a substrate on the substrate support surface; and
a second electrostatic chuck region disposed at the upper portion of the base to surround the first electrostatic chuck region, the second electrostatic chuck region having a ring support surface, and being configured to hold an edge ring on the ring support surface, in which
the second electrostatic chuck region has a supply hole, through which a heat transfer gas is supplied between an upper surface of the second electrostatic chuck region and the edge ring, and
a part of a positioning pin of the edge ring is provided inside the supply hole.

### (Appendix 8)

The substrate support according to Appendix 6 or 7, in which
a side surface of the positioning pin is formed with a groove.

### (Appendix 9)

The substrate support according to Appendix 8, in which
a plurality of the grooves are formed in the side surface of the positioning pin.

### (Appendix 10)

The substrate support according to Appendix 8 or 9, in which
the groove is formed perpendicularly to the side surface of the positioning pin.

### (Appendix 11)

The substrate support according to Appendix 8 or 9, in which
the groove is formed in a spiral shape in the side surface of the positioning pin.

### (Appendix 12)

The substrate support according to any one of Appendices 6 to 11, in which
the positioning pin is formed of a porous material.

### (Appendix 13)

The substrate support according to any one of Appendices 6 to 12, in which
the supply hole is provided with an embedded member at a lower portion of the positioning pin.

### (Appendix 14)

The substrate support according to Appendix 13, in which
an upper portion of the embedded member is formed of a conductive material, and a lower portion of the embedded member is formed of an insulating material.

### (Appendix 15)

A plasma processing apparatus including:
a plasma processing chamber;
a substrate support provided in the plasma processing chamber and configured to hold a substrate and an edge ring;
a gas supply configured to supply a processing gas to the plasma processing chamber; and
a plasma generator configured to generate plasma from the processing gas, in which
the substrate support includes
   a base,
   a first electrostatic chuck region disposed at an upper portion of the base, the first electrostatic chuck region having a substrate support surface, and being configured to hold the substrate on the substrate support surface, and
   a second electrostatic chuck region disposed at the upper portion of the base to surround the first electrostatic chuck region, the second electrostatic chuck region having a ring support surface, and being configured to hold an edge ring on the ring support surface,
the second electrostatic chuck region has a supply hole, through which a heat transfer gas is supplied between an upper surface of the second electrostatic chuck regi on and the edge ring, and
a part of a positioning pin of the edge ring is provided inside the supply hole.

### (Appendix 16)

A substrate support including:
a base;
a first electrostatic chuck region disposed at an upper portion of the base, the first electrostatic chuck region having a substrate support surface, and being configured to hold a substrate on the substrate support surface; and
a second electrostatic chuck region disposed at the upper portion of the base to surround the first electrostatic chuck region, the second electrostatic chuck region having a ring support surface, and being configured to hold an edge ring on the ring support surface, in which
the second electrostatic chuck region is provided with a positioning pin of the edge ring, the positioning pin being formed of a material having such a linear expansion coefficient that a material forming the second electrostatic chuck region is not damaged when an amount of change in a temperature of the substrate within a predetermined time is controlled to 200° C. or lower.

1. A substrate support comprising:
a base;
a first electrostatic chuck region disposed at an upper portion of the base, the first electrostatic chuck region having a substrate support surface, and the first electrostatic chuck region being configured to hold a substrate on the substrate support surface; and
a second electrostatic chuck region disposed at the upper portion of the base to surround the first electrostatic chuck region, the second electrostatic chuck region having a ring support surface, and the second electrostatic chuck region being configured to hold an edge ring on the ring support surface, wherein
the second electrostatic chuck region including a positioning pin,
the positioning pin is formed of a material having a linear expansion coefficient substantially equal to a linear expansion coefficient of a material forming the second electrostatic chuck region, and
the positioning pin is configured to contact the edge ring to move the edge ring.

2. The substrate support according to claim 1, wherein
the positioning pin is provided on an upper surface of the second electrostatic chuck region.

3. The substrate support according to claim 1, wherein
the positioning pin is formed of an insulator.

4. The substrate support according to claim 1, wherein
the positioning pin is formed of a same material as the material forming the second electrostatic chuck region.

5. The substrate support according to claim 1, wherein
the positioning pin is fixed to the second electrostatic chuck region.

6. The substrate support according to claim 1, wherein
the second electrostatic chuck region has a supply hole, through which a heat transfer gas is supplied between an upper surface of the second electrostatic chuck region and to the edge ring, and
a part of the positioning pin is provided inside the supply hole.

7. A substrate support comprising:
a base;
a first electrostatic chuck region disposed at an upper portion of the base, the first electrostatic chuck region having a substrate support surface, and the first electrostatic chuck region being configured to hold a substrate on the substrate support surface;
a second electrostatic chuck region disposed at the upper portion of the base to surround the first electrostatic chuck region, the second electrostatic chuck region including a ring support surface and a positioning pin, and the second electrostatic chuck region being configured to hold an edge ring on the ring support surface, wherein
the second electrostatic chuck region has a supply hole, through which a heat transfer gas is supplied between an upper surface of the second electrostatic chuck region and the edge ring,
the positioning pin is configured to contact the edge ring to move the edge ring, and
a part of the positioning pin is provided inside the supply hole.

8. The substrate support according to claim 7, wherein
a side surface of the positioning pin is formed with at least one groove.

9. The substrate support according to claim 8, wherein
the at least one groove of the positioning pin includes a plurality of the grooves.

10. The substrate support according to claim 8, wherein
the at least one groove of the positioning pin is formed perpendicularly to the side surface of the positioning pin.

11. The substrate support according to claim 8, wherein
the at least one groove of the positioning pin is formed in a spiral shape in the side surface of the positioning pin.

12. The substrate support according to claim 7, wherein
the positioning pin is formed of a porous material.

13. The substrate support according to claim 7, wherein
the supply hole is provided with an embedded member at a lower portion of the positioning pin.

14. The substrate support according to claim 13, wherein
an upper portion of the embedded member is formed of a conductive material, and
a lower portion of the embedded member is formed of an insulating material.

15. A plasma processing apparatus comprising:
a plasma processing chamber;
a substrate support provided in the plasma processing chamber and configured to hold a substrate and an edge ring;
a gas supply configured to supply a processing gas to the plasma processing chamber; and
a plasma generator configured to generate plasma from the processing gas, wherein
the substrate support includes
a base;
a first electrostatic chuck region disposed at an upper portion of the base; the first electrostatic chuck region having a substrate support surface, and being configured to hold the substrate on the substrate support surface;
a second electrostatic chuck region disposed at the upper portion of the base to surround the first electrostatic chuck region, the second electrostatic chuck region having a ring support surface and a positioning pin, and the second electrostatic chuck region configured to hold an edge ring on the ring support surface, wherein
the second electrostatic chuck region has a supply hole, through which a heat transfer gas is supplied between an upper surface of the second electrostatic chuck region and the edge ring,
the positioning pin is configured to contact the edge ring to move the edge ring, and
a part of the positioning pin is provided inside the supply hole.

16. The plasma processing apparatus according to claim 15, wherein
the positioning pin is formed of a material having a linear expansion coefficient substantially equal to a linear expansion coefficient of a material forming the second electrostatic chuck region to avoid damage to the second electrostatic chuck region when an amount of change in a temperature of the substrate within a predetermined time is controlled to 200° C. or lower.

17. The plasma processing apparatus according to claim 15, wherein
the positioning pin is provided on the upper surface of the second electrostatic chuck region, and
the positioning pin is formed of an insulator.

18. The plasma processing apparatus according to claim 15, wherein
a side surface of the positioning pin is formed with a groove.

19. The plasma processing apparatus according to claim 18, wherein
the groove of the position pin is formed in a spiral shape in the side surface of the positioning pin.

20. The plasma processing apparatus according to claim 15, wherein
the supply hole is provided with an embedded member at a lower portion of the positioning pin.
